(19) United States
(12) Patent Application Publication
(10) Pub. No.: US 2013/0153278 A1
(43) Pub. Date: Jun. 20, 2013

(54) BALL GRID ARRAY PACKAGE AND METHOD OF MANUFACTURING THE SAME

(71) Applicant: Samsung Electro-Mechanics Co., Ltd., Suwon (KR)

(72) Inventor: Joo Sub Maeng, Suwon (KR)

(73) Assignee: Samsung Electro-Mechanics Co., Ltd., Suwon (KR)

(21) Appl. No.: 13/720,266

(22) Filed: Dec. 19, 2012

(30) Foreign Application Priority Data
Dec. 20, 2011 (KR) 10-2011-0138350

(51) Int. Cl. H05K 1/11; H05K 13/04

(52) U.S. Cl. CPC H05K 1/111; H05K 13/0465
USPC 174/260; 228/180.21

(57) ABSTRACT

Disclosed herein is a ball grid array (BGA) package including: a printed circuit board (PCB) in which a device is mounted via solder balls, wherein the PCB includes a plurality of pad patterns each including the solder balls and having the same shape.

A uniform amount of solder balls is included in the pad patterns having the same shape, and thus the BGA package according to the present invention can prevent a short or open from occurring due to a conventional problem of an excessive or small amount of solder balls.

### CROSS REFERENCE TO RELATED APPLICATION

This application claims the benefit of Korean Patent Application No. 10-2011-0138350, filed on Dec. 20, 2011, entitled “Ball Grid Array Package and Manufacturing Method Thereof”, which is hereby incorporated by reference in its entirety into this application.

### BACKGROUND OF THE INVENTION

1. Technical Field

The present invention relates to a ball grid array (BGA) package and a method of manufacturing the same.

2. Description of the Related Art

A size of a package becomes reduced according to a trend of a small-sized and lightweight electronic device, and thus efforts to develop a more economical and reliable package have continued according to a high integration and high performance semiconductor chip. Such efforts result in various types of packages. Conventional mainstream packages are ball grid array (BGA) packages having external electric connection means in a grid array.

As described in Korean Patent Laid-Open Publication No. 2005-0046091 (laid-open published on May 18, 2005), the BGA package advantageously deals with appropriately an increase in the number of input and output pins of a semiconductor chip, reduces an induction component of an electric connection unit, and reduces a package size to a semiconductor chip size.

However, if the conventional BGA package is mounted on a printed circuit board (PCB) via solder balls using a surface mounting technology (SMT), since an amount of solder balls is not uniform, the conventional BGA package is tilted to one side.

Further, if the amount of solder balls is excessive in order to mount the conventional BGA package on the PCB, adjacent solder balls are adhered to each other during a mounting process, which a short occurs.

Meanwhile, if the amount of solder balls is small in order to mount the conventional BGA package on the PCB, an open occurs that solder balls and pads do not bond each other during the mounting process.

### SUMMARY OF THE INVENTION

The present invention has been made in an effort to provide a ball grid array (BGA) package formed by setting pad patterns each having a uniform amount of solder balls.

Further, the present invention has been made in an effort to provide a method of manufacturing a BGA package including pad patterns to achieve the above object.

According to a first preferred embodiment of the present invention, there is provided a ball grid array (BGA) package including: a printed circuit board (PCB) in which a device is mounted via solder balls, wherein the PCB includes a plurality of pad patterns each including the solder balls and having the same shape.

The plurality of pad patterns may include pads; and lead lines led from one side of the pads.

The lead lines may each be electrically connected to circuits of the PCB, and line widths thereof may have ratios of 1/10˜½ with respect to widths of the pads.

The PCB may further include a solder resist (SR) surrounding each of the plurality of pad patterns.

The number of the pad patterns may be determined according to a size of a region in which the device is mounted or the number of input and output pins of the device.

According to another preferred embodiment of the present invention, there is provided a method of manufacturing a BGA package, the method including: setting a mounting region of a PCB in which a device is mounted; and mounting the device on the mounting region via solder balls.

The setting of the mounting region may include: designing pad patterns having the same to shape included in the mounting region; forming a plurality of pad patterns in the mounting region according to design information; and uniformly forming solder balls in each of the plurality of pad patterns.

In the mounting the device on the mounting region, the solder balls may be uniformly deposited on the mounting region and the device may be soldered in the mounting region by the solder balls through a reflow process.

### BRIEF DESCRIPTION OF THE DRAWINGS

FIG. 1 is an exemplary view for explaining a ball grid array (BGA) package according to an embodiment of the present invention;

FIG. 2 is an enlarged view of a mounting region “A” of FIG. 1;

FIG. 3 is an exemplary view of a mounting region including solder balls corresponding to FIG. 2;

FIG. 4 is a flowchart of explaining a method of manufacturing a BGA package according to an embodiment of the present invention; and

FIG. 5 is an exemplary view for explaining a method of manufacturing a BGA package according to an embodiment of the present invention.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. In the description, the terms “first,” “second,” and so on are used to distinguish one element from another element, and the elements are not defined by the above terms. Further, in describing the present invention, a detailed description of related known functions or configurations will be omitted so as not to obscure the subject of the present invention.

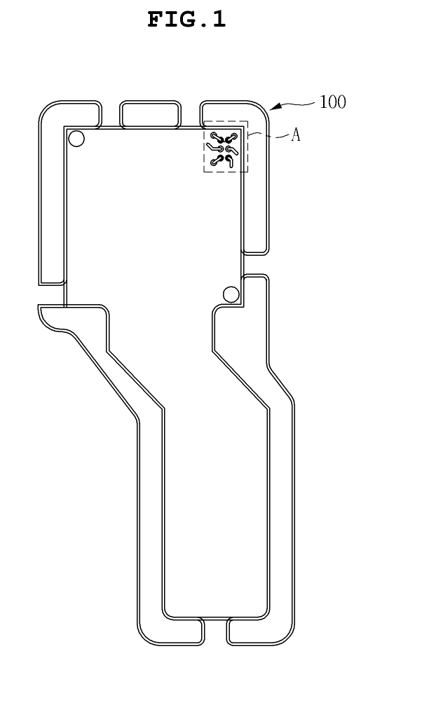

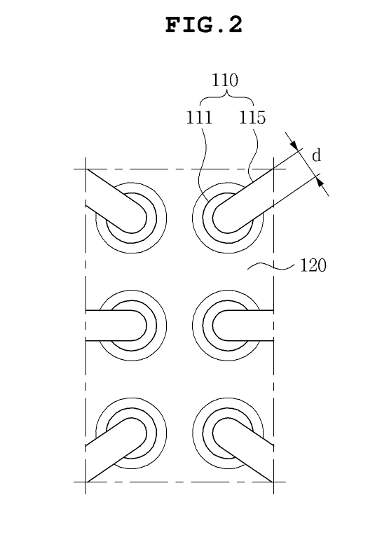

Hereinafter, preferred embodiments of the present invention will now be described in detail with reference to the accompanying drawings. FIG. 1 is an exemplary view for explaining a ball grid array (BGA) package according to an embodiment of the present invention. FIG. 2 is an enlarged view of a mounting region “A” of FIG. 1.

The BGA package of the present embodiment is a BGA package in which an IC chip or an image signal processor (ISP) chip (not shown) is mounted in the mounting region “A” of a printed circuit board (PCB) 100 of FIG. 1 via solder balls.

The mounting region “A” of the PCB 100 of the BGA package of the present embodiment in which a chip device such as the IC chip or the ISP chip is mounted includes a plurality of pad patterns 110 as shown in FIG. 2.

More specifically, the pad patterns 110 include circular pads 111 and lead lines 115 led from one side of the pads 111, and include a pad pattern of a signal end, a pad pattern of a power end, and a pad pattern of a ground end of the same shape.

The pads 111 which are electrode parts for an electrical connection are not limited to circular shapes as shown in FIG. 2 but may have polygonal shapes such as oval shapes, rectangular shapes, etc.

The lead lines 115 are led from one side of the pads 111, and are electrically connected to circuit sides included in the PCB 100, such as a circuit side of a signal processing side, a circuit of a power side, and a circuit of a ground side respectively.

The lead lines 115 have the same line width d with respect to the pads 111 and are led from one side of the pads 111. The line width d is set as a ratio of 1/10˜½ with respect to widths of the pads 111 including parts where the lead lines 115 are formed.

The pad patterns 110 set as above are surrounded by a solder resist (SR) 120. Thereafter, the chip device such as the IC chip or the ISP chip is soldered and mounted in the pad patterns 110 of the PCB 100 through a reflow process after solder balls are coated on the pad patterns 110.

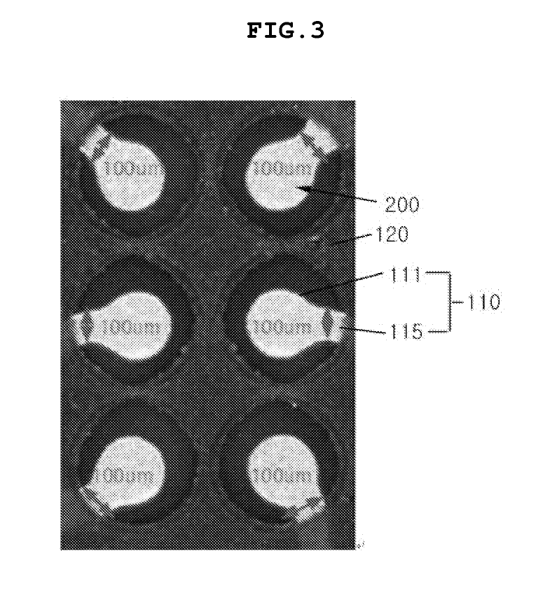

That is, as shown in FIG. 3, after solder balls 200 are coated on the pad patterns 110, a chip device is soldered and mounted through a reflow process.

In this regard, the pad patterns 110 including the lead lines 115 having the width d of, for example, 100 μm, and the circular pads 111 have the same shape, and thus areas of the pad patterns 110 are the same. Since the pad patterns 110 have the same area, the solder balls 200 included in each of the pad patterns 110 may have a uniform amount.

Owing to the uniform amount of the solder balls 200, the BGA package of the present embodiment can prevent a short or open from occurring due to the conventional problem of an excessive or small amount of solder balls.

Further, the solder balls 200 having the uniform amount are included in each of the pad patterns 110, and thus the BGA package of the present embodiment can solve a problem that the chip device is tilted during a process of mounting the chip device and forming the BGA package.

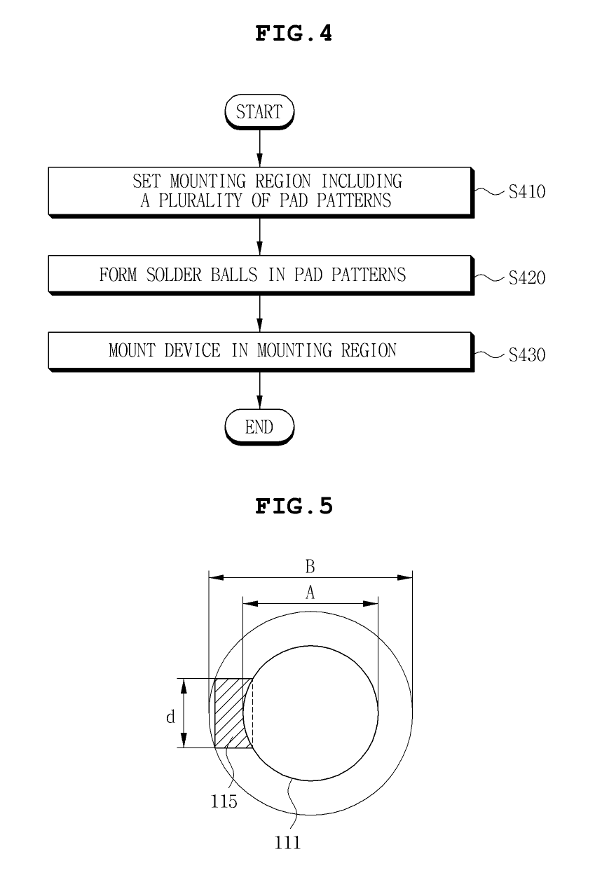

Hereinafter, a method of manufacturing the BGA package according to an embodiment of the present invention will now be described with reference to FIGS. 4 and 5. FIG. 4 is a flowchart of explaining a method of manufacturing a BGA package according to an embodiment of the present invention. FIG. 5 is an exemplary view for explaining a method of manufacturing a BGA package according to an embodiment of the present invention.

The method of manufacturing the BGA package of the present embodiment is characterized in setting a mounting region including a design of the pad patterns 110 in which a device is mounted and including the solder balls 200. Other manufacturing processes may use general manufacturing processes.

Referring to FIG. 4, the method of manufacturing the BGA package of the present embodiment sets the mounting region of the PCB 100 in which the device is mounted (S410).

More specifically, since the device is mounted in the mounting region “A” of the PCB 100 of FIG. 1 via solder balls, the method of manufacturing the BGA package of the present embodiment designs the pad patterns 110 constituting the mounting region.

To design the pad patterns 110, sizes of the pads 111 and the lead lines 115 included in the pad patterns 110 of FIG. 5 are set.

The number of the pads 111 is determined according to a size of the mounting region and the number of input and output pins of the mounted device, etc., and shapes thereof may be set as polygonal shapes such as circular, oval, or rectangular shapes.

The lead lines 115 are led from one side of the pads 111 as shown in FIG. 5. The line width d is set as a ratio of 1/10˜½ with respect to widths A of the pads 111 including parts where the lead lines 115 are formed.

In this regard, a rate of the line width d may be set in proportion to an amount of current applied to the pad patterns 110. That is, if a great amount of current is applied to the pad patterns 110, the line widths d of the lead lines 115 may be set as ½ of widths of the pads 111. Meanwhile, if a small amount of current is applied to the pad patterns 110, the line widths d of the lead lines 115 may be set as 1/10 of the widths of the pads 111.

Further, a diameter B of the SR surrounding the pad patterns 110 is set while the pad patterns 110 are set, and thus the SR may be formed in an exterior region with respect to the diameter B thereof.

After the plurality of pad patterns 110 are designed, the mounting region of the PCB 100 is formed according to setting information of the mounting region including the designed pad patterns 110.

That is, the pad patterns 110 are formed in the mounting region “A” of the PCB 100 of FIG. 1 through a patterning process using an electric and conductive material.

After the pad patterns 110 are formed, solder balls are formed in each of the pad patterns 110 (S420).

That is, the solder balls 200 are coated on each of the pad patterns 110 with respect to the mounting region “A” of the PCB 100 formed according to the setting information of the pad patterns 110 shown in FIG. 2.

After the solder balls 200 are coated on each of the pad patterns 110, a chip device is mounted in the mounting region via the solder balls 200 (S430).

More specifically, the chip device is soldered and mounted in the mounting region including the plurality of pad patterns 110 by performing a reflow process using the solder balls 200 coated on each of the pad patterns 110.

Thus, as shown in FIG. 3, the solder balls 200 uniformly solder and cover each of the pad patterns 110 including the circular pads 111 and the lead lines 115 having the same width.

Therefore, each of the pad patterns 110 has a uniform amount of the solder balls 200, and thus the BGA package having the chip device mounted can solve conventional problems of short, open, and tilting.

Hereinafter, the features of the BGA package according to the present invention will now be described in more detail using the following example and comparison example. In this regard, the following example and comparison example are used to exemplify the present invention but the scope of the invention is not limited by the following example and comparison example.

### Example

The example exemplified a structure of the six pad patterns 110 in the same shape including the circular pads 111 having the diameter A of 200 μm and the lead lines 115 having the line widths d of 100 μm shown in FIG. 2 by applying the structure of the pad patterns 110 according to the present invention.

A reflow process using solder balls was performed on the pad patterns 110 of the example, and an IC chip device was soldered and mounted in a mounting region including the pad patterns 110.

### Comparison Example

In comparison of the structure of the pad patterns 110 according to the present invention, the comparison example included conventionally different pad patterns of a signal end and a power supply end with respect to a structure of six pad patterns like the mounting region shown in FIG. 2.

That is, referring to FIG. 5, the pad pattern of the signal end included circular pads having the diameter A of 200 μm and lead lines having the line widths d of 70 μm.

Further, the pad pattern of the power supply end included circular pads having the diameter A of 200 μm and lead lines having the line widths d of 150 μm.

A reflow process using solder balls is performed on the pad patterns of the comparison example, and an IC chip device is soldered and mounted in a mounting region including the pad patterns.

An open defective rate, a short defective rate, and characteristics of an average tilt of each BGA package of the comparison example and the embodiment were detected. In this regard, the average tilt is an average value of tilted high and low lengths of one end portion of the mounted IC chip device with respect to a reference surface parallel to a surface of a PCB.

According to the open defective rate, the short defective rate, and the characteristics of the average tilt of each BGA package of the comparison example and the embodiment, it may be appreciated that the BGA package of the example to which the structure of the pad patterns 110 according to the present invention is applied is remarkably excellent as listed in Table 1 below.

TABLE 1

| | Open | Short | Average |
|---|---|---|---|
| | defective rate | defective rate | tilt (mm) |
| Comparison Example | 0.47% | 0.25% | 0.1775 |
| Example | 0.06% | 0.03% | 0.0965 |

Therefore, the BGA package to which the structure of the pad patterns 110 according to the present invention is applied can solve the conventional problems of short, open, and tilt, and enhance reliability of the BGA package.

According to the present invention, the BGA package has a uniform amount of solder balls included in pad patterns having the same shape, thereby preventing a short or open from occurring due to a conventional problem of a small or excessive amount of solder balls.

Further, a uniform amount of solder balls is included in each pad pattern, and thus the method of manufacturing the BGA package according to the present invention can solve a problem that a chip device is tilted during a process of mounting the chip device and forming the BGA package.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A ball grid array (BGA) package comprising:
a printed circuit board (PCB) in which a device is mounted via solder balls,
wherein the PCB includes a plurality of pad patterns each including the solder balls and having the same shape.

2. The BGA package as set forth in claim 1, wherein the plurality of pad patterns includes:
pads; and
lead lines led from one side of the pads.

3. The BGA package as set forth in claim 2, wherein the pads have one of polygonal shapes including a circular shape, an oval shape, and a rectangular shape.

4. The BGA package as set forth in claim 2, wherein the lead lines each are electrically connected to circuits of the PCB, and line widths thereof have ratios of 1/10˜½ with respect to widths of the pads.

5. The BGA package as set forth in claim 1, wherein the PCB further includes a solder resist (SR) surrounding each of the plurality of pad patterns.

6. The BGA package as set forth in claim 1, wherein the number of the pad patterns is determined according to a size of a region in which the device is mounted or the number of input and output pins of the device.

7. A method of manufacturing a BGA package, the method comprising:
setting a mounting region of a PCB in which a device is mounted; and
mounting the device on the mounting region via solder balls.

8. The method as set forth in claim 7, wherein the setting of the mounting region includes:
designing pad patterns having the same shape included in the mounting region;
forming a plurality of pad patterns in the mounting region according to design information; and
uniformly forming solder balls in each of the plurality of pad patterns.

9. The method as set forth in claim 8, wherein the plurality of pad patterns include pads and lead lines led from one side of the pads, and
wherein the pads have polygonal shapes.

10. The method as set forth in claim 9, wherein line widths of the lead lines are proportional to an amount of current applied to the plurality of pad patterns, and have ratios of 1/10 ˜½ with respect to widths of the pads.

11. The method as set forth in claim 8, wherein the designing of the pad patterns includes forming an SR surrounding each of the plurality of pad patterns.

12. The method as set forth in claim 7, wherein the mounting the device on the mounting region, the solder balls are uniformly deposited on the mounting region, and the device is soldered on the mounting region by the solder balls through a reflow process.
